(19) United States
(12) Patent Application Publication
(10) Pub. No.: US 2019/0140163 A1
(43) Pub. Date: May 9, 2019

(54) MAGNETIC MEMORY DEVICES

(71) Applicant: Samsung Electronics Co., Ltd., Suwon-si (KR)

(72) Inventors: Sangjun Yun, Hwaseong-si (KR); Sang-Kuk Kim, Seongnam-si (KR); Jae Hoon Kim, Seoul (KR); Eunsun Noh, Yongin-si (KR); Se Chung Oh, Yongin-si (KR); Sung Chul Lee, Osan-si (KR); Daeeun Jeong, Yongin-si (KR)

(21) Appl. No.: 16/021,708

(22) Filed: Jun. 28, 2018

(30) Foreign Application Priority Data
Nov. 8, 2017 (KR) 10-2017-0148212

(51) Int. Cl. H01L 43/02; H01L 43/10; G11C 11/16; H01L 27/22; H01L 43/12

(52) U.S. Cl. CPC H01L 43/02; H01L 43/10; H01L 43/12; H01L 27/222; G11C 11/161

(57) ABSTRACT

Magnetic memory devices are provided. A magnetic memory device includes a first electrode on a substrate, a magnetic tunnel junction pattern including a first magnetic layer, a tunnel barrier layer, and a second magnetic layer, which are sequentially stacked on the first electrode, and a second electrode on the magnetic tunnel junction pattern. A surface binding energy of the first electrode and/or the second electrode with respect to the magnetic tunnel junction pattern is relatively low.

### CROSS-REFERENCE TO RELATED APPLICATION

This U.S. non-provisional patent application claims priority under 35 U.S.C. § 119 to Korean Patent Application No. 10-2017-0148212, filed on Nov. 8, 2017, in the Korean Intellectual Property Office, the disclosure of which is hereby incorporated by reference in its entirety.

### BACKGROUND

The present disclosure relates to memory devices and, more particularly, to magnetic memory devices. High-speed and low-voltage memory devices have been demanded to realize high-speed and low-power electronic devices including memory devices. A magnetic memory device has been studied as a memory device satisfying these demands. The magnetic memory device has been spotlighted as a next-generation memory device because of its high-speed operation characteristic and/or non-volatile characteristic.

A magnetic memory device may use a magnetic tunnel junction (MTJ). The magnetic tunnel junction may include two magnetic layers and a tunnel barrier layer disposed between the two magnetic layers, and a resistance of the magnetic tunnel junction may be changed according to magnetization directions of the two magnetic layers. In detail, the magnetic tunnel junction may have a high resistance when the magnetization directions of the two magnetic layers are anti-parallel to each other. On the contrary, the magnetic tunnel junction may have a low resistance when the magnetization directions of the two magnetic layers are parallel to each other. The magnetic memory device may write/sense data by using a difference between the resistances of the magnetic tunnel junction.

In particular, a spin transfer torque magnetic random access memory (STT-MRAM) device has been spotlighted as a highly integrated memory device because of its property that the amount of the writing current decreases as a size of a magnetic cell decreases. Operation of a magnetic memory device may be degraded, however, if an electrical short is formed between two magnetic layers of a magnetic tunnel junction of the magnetic memory device.

### SUMMARY

Embodiments of the inventive concepts may provide a magnetic memory device with improved electrical characteristics.

In some embodiments, a magnetic memory device may include a bottom electrode on a substrate, a magnetic tunnel junction pattern including a first magnetic layer, a tunnel barrier layer, and a second magnetic layer, which are sequentially stacked on the bottom electrode, and a top electrode on the magnetic tunnel junction pattern. The bottom electrode may include a first material and the top electrode may include a second material. A first surface binding energy of the first material with respect to the magnetic tunnel junction pattern may be lower than a second surface binding energy of the second material with respect to the magnetic tunnel junction pattern.

In some embodiments, a magnetic memory device may include a first electrode on a substrate, a magnetic tunnel junction pattern including a first magnetic layer, a tunnel barrier layer, and a second magnetic layer, which are sequentially stacked on the first electrode, and a second electrode on the magnetic tunnel junction pattern. The first electrode may be between the second electrode and the substrate. At least one of the first electrode or the second electrode may include a low-energy electrode material. A first surface binding energy of the low-energy electrode material with respect to the magnetic tunnel junction pattern may be lower than a second surface binding energy of tungsten with respect to the magnetic tunnel junction pattern.

In some embodiments, a magnetic memory device may include a first electrode on a substrate, a magnetic tunnel junction pattern including a first magnetic layer, a tunnel barrier layer, and a second magnetic layer, which are sequentially stacked on the first electrode, and a second electrode on the magnetic tunnel junction pattern. The first electrode may be between the second electrode and the substrate. The first electrode may include a first material and a second material, and the second electrode may include the second material. A first surface binding energy of the first material with respect to the tunnel barrier layer of the magnetic tunnel junction pattern may be lower than a second surface binding energy of the second material with respect to the tunnel barrier layer of the magnetic tunnel junction pattern.

### BRIEF DESCRIPTION OF THE DRAWINGS

The inventive concepts will become more apparent in view of the attached drawings and accompanying detailed description.

FIG. 1 is a conceptual diagram illustrating a unit memory cell of a magnetic memory device including a magnetic tunnel junction pattern according to some embodiments of the inventive concepts.

FIG. 2 is a cross-sectional view illustrating a unit memory cell of a magnetic memory device including a magnetic tunnel junction pattern according to some embodiments of the inventive concepts.

FIG. 3 is an enlarged view of a portion ‘Q’ of FIG. 2.

FIG. 4 is a plan view illustrating a method of manufacturing a magnetic memory device according to some embodiments of the inventive concepts.

FIGS. 5 to 7 are cross-sectional views taken along a line I-I′ of FIG. 4 to illustrate a method of manufacturing a magnetic memory device according to some embodiments of the inventive concepts.

FIGS. 8 and 9 are conceptual diagrams illustrating magnetic tunnel junction patterns according to some embodiments of the inventive concepts.

### DETAILED DESCRIPTION

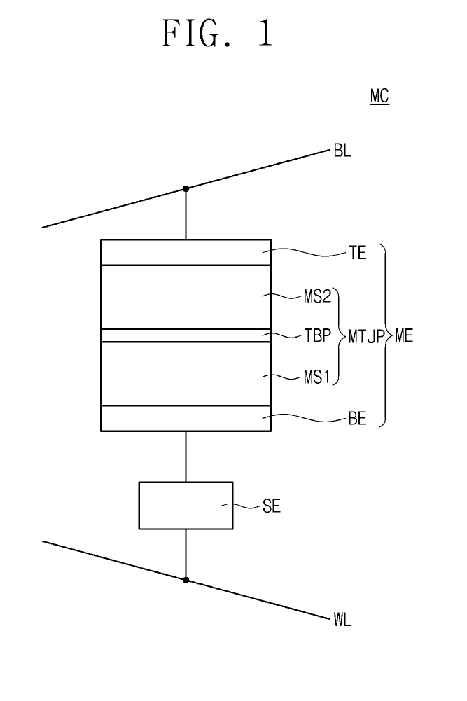

FIG. 1 is a conceptual diagram illustrating a unit memory cell of a magnetic memory device including a magnetic tunnel junction pattern according to some embodiments of the inventive concepts.

Referring to FIG. 1, a unit memory cell MC may include a memory element ME and a selection element SE which are disposed between a bit line BL and a word line WL intersecting each other. The memory element ME may include a bottom electrode BE, a magnetic tunnel junction pattern MTJP, and a top electrode TE. The memory element ME and the selection element SE may be electrically connected in series to each other.

The selection element SE may selectively control a flow of charges passing through the magnetic tunnel junction pattern MTJP. For example, the selection element SE may be a diode, a PNP bipolar transistor, an NPN bipolar transistor, an NMOS field effect transistor, or a PMOS field effect transistor. When the selection element SE is a three-terminal element (e.g., the bipolar transistor or the MOS field effect transistor), an additional interconnection line may be connected to the selection element SE. The magnetic tunnel junction pattern MTJP may include a first magnetic pattern MS1, a second magnetic pattern MS2, and a tunnel barrier pattern TBP between the first and second magnetic patterns MS1 and MS2. Each of the first and second magnetic patterns MS1 and MS2 may include at least one magnetic layer.

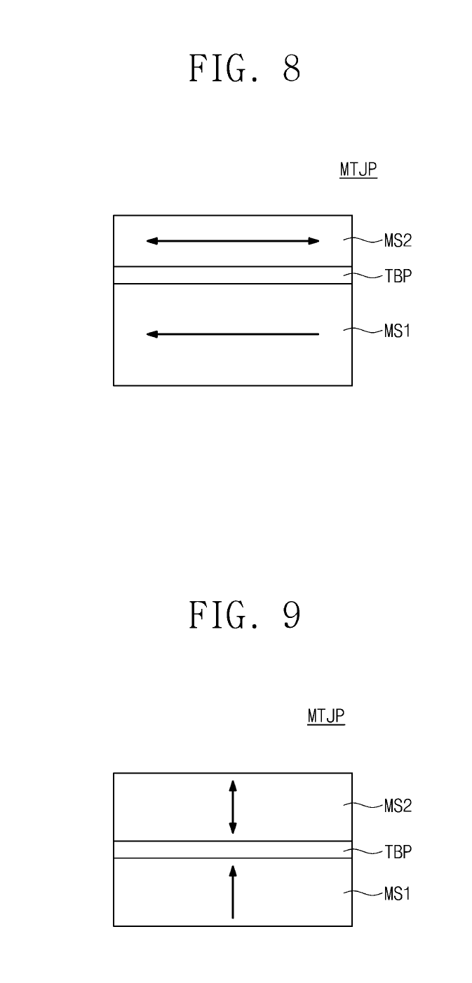

A magnetization direction of one of the first and second magnetic patterns MS1 and MS2 may be fixed regardless of an external magnetic field in a general use environment. In the present specification, a magnetic layer having the fixed magnetization property (i.e., the fixed magnetization direction) is defined as a reference layer. The reference layer may include a pinning layer and a pinned layer. A magnetization direction of the other of the first and second magnetic patterns MS1 and MS2 may be switched by an external magnetic field applied thereto or spin torque of electrons of a program current applied thereto. In the present specification, a magnetic layer having the switchable or changeable magnetization property (i.e., the switchable or changeable magnetization direction) is defined as a free layer. An electrical resistance of the magnetic tunnel junction pattern MTJP may be dependent on the magnetization directions of the free layer and the reference layer. For example, an electrical resistance of the magnetic tunnel junction pattern MTJP when the magnetization directions of the free and reference layers are anti-parallel to each other may be much higher than that of the magnetic tunnel junction pattern MTJP when the magnetization directions of the free and reference layers are parallel to each other. As a result, the electrical resistance of the magnetic tunnel junction pattern MTJP may be adjusted by changing the magnetization direction of the free layer. This principle may be used as a principle of storing data in the magnetic memory device according to some embodiments of the inventive concepts. The first and second magnetic patterns MS1 and MS2 and the tunnel barrier pattern TBP will be described later in more detail with reference to FIGS. 8 and 9.

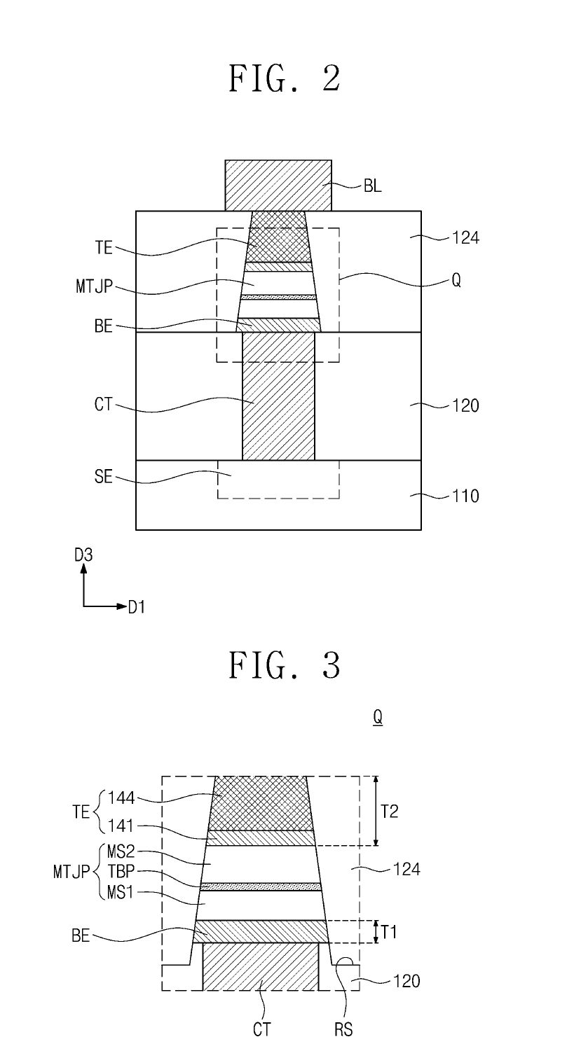

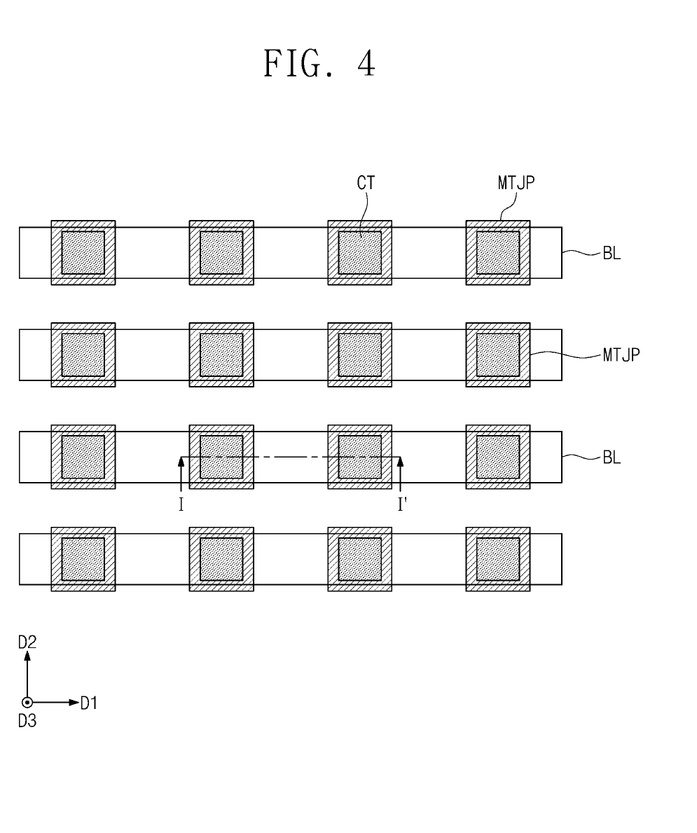

FIG. 2 is a cross-sectional view illustrating a unit memory cell of a magnetic memory device including a magnetic tunnel junction pattern according to some embodiments of the inventive concepts. FIG. 3 is an enlarged view of a portion ‘Q’ of FIG. 2.

Referring to FIGS. 2 and 3, a substrate 110 may be provided. For example, the substrate 110 may be a silicon substrate, a silicon-on-insulator (SOI) substrate, or a germanium substrate. The substrate 110 may include a selection element SE. For example, the selection element SE may be a selection element including a word line.

A contact plug CT connected to the selection element SE may be provided. The contact plug CT may penetrate a first interlayer insulating layer 120 disposed on the substrate 110 and may be connected to one terminal of the selection element SE. The contact plug CT may include at least one of a doped semiconductor material (e.g., doped silicon), a metal (e.g., tungsten, titanium, or tantalum), a conductive metal nitride (e.g., titanium nitride, tantalum nitride, or tungsten nitride), or a metal-semiconductor compound (e.g., a metal silicide). A bottom electrode BE, a magnetic tunnel junction pattern MTJP and a top electrode TE may be sequentially provided on the contact plug CT.

The magnetic tunnel junction pattern MTJP may include a first magnetic pattern MS1, a second magnetic pattern MS2, and a tunnel barrier pattern TBP between the first and second magnetic patterns MS1 and MS2. The bottom electrode BE, the magnetic tunnel junction pattern MTJP and the top electrode TE may be provided in a second interlayer insulating layer 124. For example, each of the first and second interlayer insulating layers 120 and 124 may include at least one of a silicon oxide layer, a silicon nitride layer, or a silicon oxynitride layer.

At least one of the bottom electrode BE or the top electrode TE may include a low-energy electrode material. For example, in some embodiments, the bottom electrode BE may include the low-energy electrode material and the top electrode TE may be free of (i.e., may omit) the low-energy electrode material. A surface binding energy of the low-energy electrode material with respect to the tunnel barrier pattern TBP may be less (i.e., lower) than a surface binding energy of tungsten with respect to the tunnel barrier pattern TBP. In the present specification, the surface binding energy means an energy required to remove or separate one atom of a corresponding material from a surface of an the tunnel barrier pattern TBP (i.e., a surface of attached component), unless otherwise indicated. For example, the low-energy electrode material may be copper (Cu), aluminum (Al), germanium (Ge), carbon (C), scandium (Sc), titanium (Ti), tantalum (Ta), or vanadium (V). For example, the low-energy electrode material may have an atomic weight/mass less (i.e., lower) than that of tungsten. The surface binding energies of the low-energy electrode materials are shown in the following table 1 and are less (i.e., lower) than 2.72 eV, which is the surface binding energy of tungsten (W).

TABLE 1

| Element | Cu | Al | Ge | C | Sc | Ti | Ta | V |
|---|---|---|---|---|---|---|---|---|
| Surface binding | 0.99 | 1.23 | 1.02 | 2.24 | 1.80 | 2.25 | 2.25 | 2.68 |
| energy (eV) | | | | | | | | |

The surface binding energies of the low-energy electrode materials were measured based on an energy required to remove or separate one atom of a corresponding material from a surface of a magnesium oxide (MgO) layer used as the tunnel barrier pattern TBP, as described above.

According to some embodiments of the inventive concepts, the low-energy electrode material, the surface binding energy of which is less (i.e., lower) than that of tungsten that is generally used as an electrode material, may be used as the electrode material, and thus it is possible to inhibit or prevent a short phenomenon between the first and second magnetic patterns MS1 and MS2 which may be caused by re-deposition of the electrode material on a sidewall of the tunnel barrier pattern TBP in a patterning process of forming the electrode. In other words, when the low-energy electrode material is used as the electrode material, it is possible to inhibit or prevent a conductive residue from being formed on the sidewall of the tunnel barrier pattern TBP.

According to some embodiments of the inventive concepts, the bottom electrode BE may include a conductive layer including the low-energy electrode material. For example, the bottom electrode BE may include a copper layer, an aluminum layer, a germanium layer, a carbon layer, a scandium layer, a titanium layer, a tantalum layer, or a vanadium layer. The germanium layer may be doped with a group III element or a group V element. The carbon layer may have a conductive crystal structure such as graphene.

According to some embodiments of the inventive concepts, the bottom electrode BE may include a conductive metal nitride layer of the low-energy electrode material. For example, the bottom electrode BE may include an aluminum nitride layer, a titanium nitride layer, a tantalum nitride layer, or a vanadium nitride layer. In some embodiments, the bottom electrode BE may include a layer of the low-energy electrode material and the conductive metal nitride layer of the low-energy electrode material.

According to some embodiments of the inventive concepts, the top electrode TE may include a conductive layer including the low-energy electrode material. For example, the top electrode TE may include a copper layer, an aluminum layer, a germanium layer, a carbon layer, a scandium layer, a titanium layer, a tantalum layer, or a vanadium layer. The germanium layer may be doped with a group III element or a group V element. The carbon layer may have a conductive crystal structure such as graphene.

According to some embodiments of the inventive concepts, the top electrode TE may include a conductive metal nitride layer of the low-energy electrode material. For example, the top electrode TE may include an aluminum nitride layer, a titanium nitride layer, a tantalum nitride layer, or a vanadium nitride layer. In some embodiments, the top electrode TE may include a layer of the low-energy electrode material and the conductive metal nitride layer of the low-energy electrode material. In some embodiments, the top electrode TE may be formed of the same material as the bottom electrode BE. Alternatively, the top electrode TE may be formed of a material different from that of the bottom electrode BE.

According to some embodiments of the inventive concepts, the bottom electrode BE may include a first material and the top electrode TE may include a second material. A surface binding energy of the first material with respect to the tunnel barrier pattern TBP may be less (i.e., lower) than a surface binding energy of the second material with respect to the tunnel barrier pattern TBP. Since the top electrode TE is used as a mask for forming the magnetic tunnel junction pattern MTJP, an etch resistance of the second material to an etching process (e.g., to an ion beam of an etching process) may be greater (i.e., higher) than an etch resistance of the first material to the etching process (e.g., to the ion beam of the etching process). As a result, the re-deposition phenomenon may be inhibited, minimized, or prevented without increasing a thickness of the magnetic tunnel junction pattern MTJP.

In some embodiments, the first material may be one of the low-energy electrode materials shown in the table 1. In other words, the first material may be copper (Cu), aluminum (Al), germanium (Ge), carbon (C), scandium (Sc), titanium (Ti), tantalum (Ta), or vanadium (V). The second material may be tungsten. The bottom electrode BE may include a layer of the first material and/or a conductive nitride layer of the first material. The top electrode TE may include a tungsten layer and/or a tungsten nitride layer.

In some embodiments, a group number of the first material in a periodic table may be greater (i.e., higher) than a group number of the second material in the periodic table. For example, the first material may be a material of International Union of Pure and Applied Chemistry (IUPAC) groups 11 to 14, and the second material may be a material of IUPAC groups 3 to 6. The first material may be selected from a first material group of the following table 2, and the second material may be selected from a second material group of the following table 2. In other words, the first material may be copper (Cu), aluminum (Al), germanium (Ge), or carbon (C), and the second material may be scandium (Sc), titanium (Ti), tantalum (Ta), vanadium (V), or tungsten (W). The bottom electrode BE may include a layer of the first material and/or a conductive nitride layer of the first material. The top electrode TE may include a layer of the second material and/or a conductive nitride layer of the second material.

TABLE 2

| | First material group | | | | Second material group | | | | |
|---|---|---|---|---|---|---|---|---|---|
| Element | Cu | Al | Ge | C | Sc | Ti | Ta | V | W |
| Surface | 0.99 | 1.23 | 1.02 | 2.24 | 1.80 | 2.25 | 2.25 | 2.68 | 2.72 |
| binding | | | | | | | | | |
| energy | | | | | | | | | |
| (eV) | | | | | | | | | |

In some embodiments, the bottom electrode BE may include a first material and a second material, and the top electrode TE may include the second material. A surface binding energy of the first material with respect to the tunnel barrier pattern TBP may be less (i.e., lower) than a surface binding energy of the second material with respect to the tunnel barrier pattern TBP. For example, when the second material is tungsten (W), the bottom electrode BE may include a compound of tungsten (W) and at least one of copper (Cu), aluminum (Al), germanium (Ge), carbon (C), scandium (Sc), titanium (Ti), tantalum (Ta), or vanadium (V). A weight ratio of the first material to the second material in the bottom electrode BE may range from about 1:1 to about 1:20. A ratio of the first material in the bottom electrode BE may range from about 5 wt % to about 50 wt %.

The bottom electrode BE may include a compound layer of the first material and the second material and/or a conductive nitride layer of the first material and the second material. The top electrode TE may include a layer of the second material and/or a conductive nitride layer of the second material.

In some embodiments, each of the bottom and top electrodes BE and TE may include the first material and the second material. In some embodiments, a ratio/concentration of the first material in the bottom electrode BE may be substantially equal to a ratio/concentration of the first material in the top electrode TE. For example, the ratio/concentration of the first material in each of the bottom and top electrodes BE and TE may range from about 5 wt % to about 50 wt %. Alternatively, the ratio/concentration of the first material in the bottom electrode BE may be greater (i.e., higher) than the ratio/concentration of the first material in the top electrode TE. For example, the ratio/concentration of the first material in the bottom electrode BE may range from about 15 wt % to about 50 wt %, and the ratio/concentration of the first material in the top electrode TE may range from about 5 wt % to about 15 wt %. Each of the bottom and top electrodes BE and TE may include a compound layer of the first material and the second material and/or a conductive nitride layer of the first material and the second material.

A thickness T2 of the top electrode TE may be greater (i.e., thicker) than a thickness T1 of the bottom electrode BE. For example, the thickness T2 of the top electrode TE may range from about 2 times to about 10 times the thickness T1 of the bottom electrode BE. For example, the thickness T1 of the bottom electrode BE may range from about 50 Å to about 500 Å.

In some embodiments, the top electrode TE may include a metal nitride pattern 141 and a metal pattern 144 on the metal nitride pattern 141. A bit line BL may be provided on the top electrode TE. The metal nitride pattern 141 may improve adhesion of the metal pattern 144 and the magnetic tunnel junction pattern MTJP. The metal pattern 144 may be thicker than the metal nitride pattern 141. For example, a thickness of the metal pattern 144 may range from about 2 times to about 7 times a thickness of the metal nitride pattern 141. The thickness of the metal pattern 144 may range from about 250 Å to about 500 Å. The magnetic tunnel junction pattern MTJP may be thicker than the metal pattern 144. For example, a thickness of the magnetic tunnel junction pattern MTJP may range from about 1.5 times to about 2 times a thickness of the metal pattern 144. The thickness of the magnetic tunnel junction pattern MTJP may range from about 450 Å to about 800 Å.

A width in a first direction D1 of a structure including the top electrode TE, the magnetic tunnel junction pattern MTJP and the bottom electrode BE may become progressively greater (i.e., wider) from the top electrode TE toward the bottom electrode BE in a third direction D3. Accordingly, the width of the structure (e.g., including the width of the top electrode TE) may be tapered away from the substrate 110. A recess region RS which is recessed relative to a top surface of the contact plug CT may be provided in an upper portion of the first interlayer insulating layer 120.

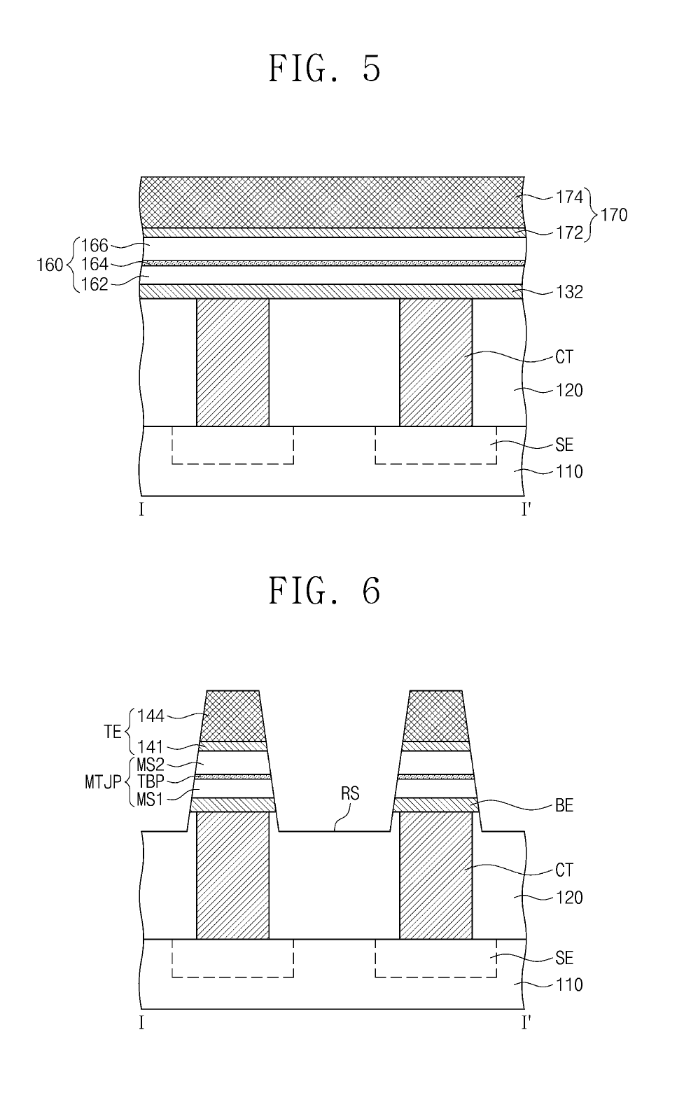

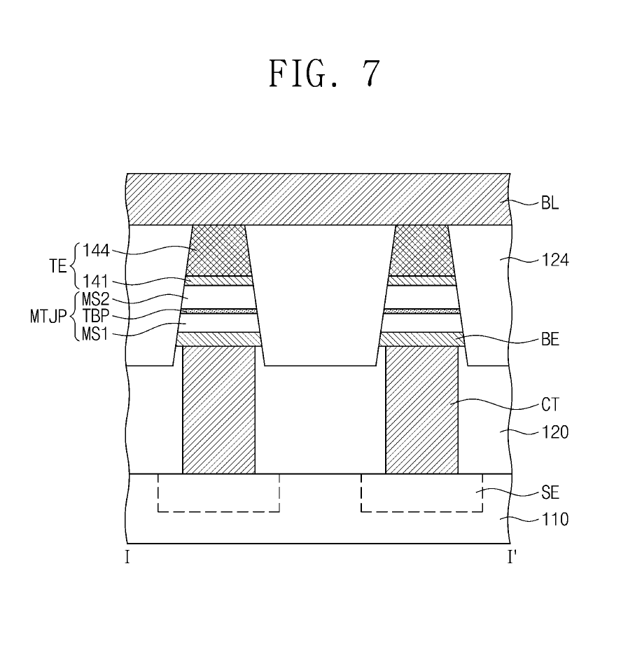

FIG. 4 is a plan view illustrating a method of manufacturing a magnetic memory device according to some embodiments of the inventive concepts. FIGS. 5 to 7 are cross-sectional views taken along a line I-I′ of FIG. 4 to illustrate a method of manufacturing a magnetic memory device according to some embodiments of the inventive concepts.

Referring to FIGS. 4 and 5, a first interlayer insulating layer 120 may be provided on a substrate 110. The substrate 110 may be a semiconductor substrate that includes silicon, silicon on an insulator (SOI), silicon-germanium (SiGe), germanium (Ge), or gallium-arsenic (GaAs). Selection elements SE may be provided in the substrate 110, and the first interlayer insulating layer 120 may cover the selection elements SE. The selection elements SE may be field effect transistors or diodes. The first interlayer insulating layer 120 may include at least one of an oxide layer, a nitride layer, a carbide layer, or an oxynitride layer. For example, the first interlayer insulating layer 120 may include at least one of a silicon oxide layer, a silicon nitride layer, a silicon carbide layer, or an aluminum oxide layer.

Contact plugs CT may be provided in the first interlayer insulating layer 120. Each of the contact plugs CT may penetrate the first interlayer insulating layer 120 so as to be electrically connected to one terminal of a corresponding (e.g., respective) one of the selection elements SE. Contact holes may be formed in the first interlayer insulating layer 120, and the contact plugs CT may be formed by filling the contact holes with a conductive material. The contact plugs CT may include at least one of a doped semiconductor material (e.g., doped silicon), a metal (e.g., tungsten, titanium, or tantalum), a conductive metal nitride (e.g., titanium nitride, tantalum nitride, or tungsten nitride), or a metal-semiconductor compound (e.g., a metal silicide). In some embodiments, top surfaces of the contact plugs CT may be substantially coplanar with a top surface of the first interlayer insulating layer 120.

A bottom electrode layer 132 may be formed on the contact plugs CT. The bottom electrode layer 132 may be formed to cover a plurality of the contact plugs CT. The bottom electrode layer 132 may be formed of the material of the bottom electrode BE described with reference to FIGS. 2 and 3. The bottom electrode layer 132 may be formed by a sputtering process. A planarization process may be performed after the formation of the bottom electrode layer 132. However, embodiments of the inventive concepts are not limited thereto.

A magnetic tunnel junction layer 160 and a top electrode layer 170 may be sequentially formed on the bottom electrode layer 132. The magnetic tunnel junction layer 160 may include a first magnetic layer 162, a tunnel barrier layer 164 and a second magnetic layer 166 which are sequentially stacked on the bottom electrode layer 132. One of the first and second magnetic layers 162 and 166 may be a reference layer (or a pinned layer) having a magnetization direction fixed in one direction, and the other of the first and second magnetic layers 162 and 166 may be a free layer having a magnetization direction changeable to be parallel or anti-parallel to the fixed magnetization direction of the reference layer.

In some embodiments, the magnetization directions of the reference layer and the free layer may be substantially perpendicular to an interface between the tunnel barrier layer 164 and the second magnetic layer 166. In some embodiments, the magnetization directions of the reference layer and the free layer may be substantially parallel to the interface between the tunnel barrier layer 164 and the second magnetic layer 166. The magnetization directions of the reference layer and the free layer will be described later in more detail with reference to FIGS. 8 and 9. Each of the first magnetic layer 162, the tunnel barrier layer 164 and the second magnetic layer 166 may be formed by a physical vapor deposition (PVD) process (e.g., a sputtering process) or a chemical vapor deposition (CVD) process.

The top electrode layer 170 may be formed of the material of the top electrode TE described with reference to FIGS. 2 and 3. For example, the top electrode layer 170 may include a metal nitride layer 172 and a metal layer 174. Alternatively, one of the metal nitride layer 172 or the metal layer 174 may be omitted.

Referring to FIGS. 4 and 6, a patterning process may be performed. The patterning process may include an ion beam etching process. First, the top electrode layer 170 may be patterned to form top electrodes TE. In some embodiments, each of the top electrodes TE may include a metal nitride pattern 141 and a metal pattern 144 on the metal nitride pattern 141. The magnetic tunnel junction layer 160 and the bottom electrode layer 132 may be patterned using the top electrodes TE as etch masks. Thus, bottom electrodes BE and magnetic tunnel junction patterns MTJP may be formed. Each of the magnetic tunnel junction patterns MTJP may include a first magnetic pattern MS1, a tunnel barrier pattern TBP, and a second magnetic pattern MS2. In the present patterning process, a recess region RS may be formed in an upper portion of the first interlayer insulating layer 120.

According to some embodiments of the inventive concepts, the bottom electrode layer 132 and/or the top electrode layer 170 may be formed of a material of which the surface binding energy with respect to the tunnel barrier pattern TBP is relatively low. As a result, it is possible to reduce or minimize a phenomenon that the electrode material is re-deposited on a sidewall of the tunnel barrier pattern TBP during the patterning process.

Referring to FIGS. 4 and 7, a second interlayer insulating layer 124 may be formed to cover sidewalls of the top electrodes TE, the magnetic tunnel junction patterns MTJP and the bottom electrodes BE. For example, the second interlayer insulating layer 124 may be formed of at least one of a silicon oxide layer, a silicon nitride layer, or a silicon oxynitride layer. For example, the second interlayer insulating layer 124 may be formed by a CVD process. In some embodiments, a protective layer covering the sidewalls of the magnetic tunnel junction patterns MTJP may be formed before the formation of the second interlayer insulating layer 124. For example, the protective layer may include a silicon nitride layer or an aluminum oxide layer.

Bit lines BL may be formed on the top electrodes TE. The bit lines BL may be formed of at least one of a metal, a metal nitride, or a doped semiconductor material. For example, the bit lines BL may be formed using a sputtering process.

FIGS. 8 and 9 are conceptual diagrams illustrating magnetic tunnel junction patterns according to some embodiments of the inventive concepts. The magnetic tunnel junction pattern MTJP may include the first magnetic pattern MS1, the tunnel barrier pattern TBP, and the second magnetic pattern MS2. One of the first and second magnetic patterns MS1 and MS2 may be a free pattern of the magnetic tunnel junction (MTJ), and the other of the first and second magnetic patterns MS1 and MS2 may be a reference pattern. Hereinafter, for the purpose of ease and convenience in explanation, the first magnetic pattern MS1 will be described as the reference pattern and the second magnetic pattern MS2 will be described as the free pattern. However, on the contrary, the first magnetic pattern MS1 may be the free pattern and the second magnetic pattern MS2 may be the reference pattern. An electrical resistance of the magnetic tunnel junction pattern MTJP may be dependent on the magnetization directions of the free pattern and the reference pattern. For example, an electrical resistance of the magnetic tunnel junction pattern MTJP when the magnetization directions of the free and reference patterns are anti-parallel to each other may be much higher than that of the magnetic tunnel junction pattern MTJP when the magnetization directions of the free and reference patterns are parallel to each other. As a result, the electrical resistance of the magnetic tunnel junction pattern MTJP may be adjusted by changing the magnetization direction of the free pattern. This principle may be used as a principle of storing data in the magnetic memory device according to some embodiments of the inventive concepts.

Referring to FIG. 8, the first and second magnetic patterns MS1 and MS2 may include magnetic layers for forming a horizontal magnetization structure in which magnetization directions are substantially parallel to a top surface of the tunnel barrier pattern TBP. In some embodiments, the first magnetic pattern MS1 may include a layer including an anti-ferromagnetic material and a layer including a ferromagnetic material. The layer including the anti-ferromagnetic material may include at least one of PtMn, IrMn, MnO, MnS, MnTe, MnF₂, FeCl₂, FeO, CoCl₂, CoO, NiCl₂, NiO, or Cr. In some embodiments, the layer including the anti-ferromagnetic material may include at least one selected from precious metals. The precious metals may include ruthenium (Ru), rhodium (Rh), palladium (Pd), osmium (Os), iridium (Ir), platinum (Pt), gold (Au), or silver (Ag). The layer including the ferromagnetic material may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂.

The second magnetic pattern MS2 may include a material having a changeable magnetization direction. The second magnetic pattern MS2 may include a ferromagnetic material. For example, the second magnetic pattern MS2 may include at least one of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂.

In some embodiments, the second magnetic pattern MS2 may include a plurality of layers. For example, the second magnetic pattern MS2 may include a plurality of ferromagnetic material layers and a non-magnetic material layer disposed between the ferromagnetic material layers. In this case, the ferromagnetic material layers and the non-magnetic material layer may constitute a synthetic anti-ferromagnetic layer. The synthetic anti-ferromagnetic layer may reduce a critical current density of the magnetic memory device and may improve thermal stability of the magnetic memory device.

The tunnel barrier pattern TBP may include at least one of magnesium oxide (MgO), titanium oxide (TiO), aluminum oxide (AlO), magnesium-zinc oxide (MgZnO), magnesium-boron oxide (MgBO), titanium nitride (TiN), or vanadium nitride (VN). For example, the tunnel barrier pattern TBP may be a single layer formed of magnesium oxide (MgO). Alternatively, the tunnel barrier pattern TBP may include a plurality of layers. The tunnel barrier pattern TBP may be formed using a CVD process.

Referring to FIG. 9, the first and second magnetic patterns MS1 and MS2 may have a perpendicular magnetization structure in which magnetization directions are substantially perpendicular to the top surface of the tunnel barrier pattern TBP. In some embodiments, each of the first and second magnetic patterns MS1 and MS2 may include at least one of a material having a L10 crystal structure, a material having a hexagonal close packed (HCP) lattice structure, or an amorphous rare-earth transition metal (amorphous RE-TM) alloy. In some embodiments, each of the first and second magnetic patterns MS1 and MS2 may include the material having the L10 crystal structure, which includes at least one of Fe₅₀Pt₅₀, Fe₅₀Pd₅₀, Co₅₀Pt₅₀, Co₅₀Pd₅₀, or Fe₅₀Ni₅₀. Alternatively, each of the first and second magnetic patterns MS1 and MS2 may include a cobalt-platinum (CoPt) disordered alloy having the HCP lattice structure and a platinum (Pt) content of 10 at % to 45 at %, or a Co₃Pt ordered alloy having the HCP lattice structure. In some embodiments, each of the first and second magnetic patterns MS1 and MS2 may include an amorphous RE-TM alloy which includes at least one of iron (Fe), cobalt (Co), or nickel (Ni) and at least one of terbium (Tb), dysprosium (Dy), or gadolinium (Gd). Tb, Dy and Gd may correspond to the rare earth metals.

In some embodiments, each of the first and second magnetic patterns MS1 and MS2 may include a material having interface perpendicular magnetic anisotropy. The interface perpendicular magnetic anisotropy means a phenomenon that a magnetic layer having an intrinsic horizontal magnetization property has a perpendicular magnetization direction by an influence of an interface between the magnetic layer and another layer adjacent to the magnetic layer. Here, the intrinsic horizontal magnetization property may mean that a magnetic layer has a magnetization direction parallel to the widest surface of the magnetic layer when an external factor does not exist. For example, when the magnetic layer having the intrinsic horizontal magnetization property is formed on a substrate and an external factor does not exist, the magnetization direction of the magnetic layer may be substantially parallel to a top surface of the substrate.

For example, each of the first and second magnetic patterns MS1 and MS2 may include at least one of cobalt (Co), iron (Fe), or nickel (Ni). In some embodiments, each of the first and second magnetic patterns MS1 and MS2 may further include at least one selected from non-magnetic materials including boron (B), zinc (Zn), aluminum (Al), titanium (Ti), ruthenium (Ru), tantalum (Ta), silicon (Si), silver (Ag), gold (Au), copper (Cu), carbon (C), and nitrogen (N). For example, each of the first and second magnetic patterns MS1 and MS2 may include CoFe or NiFe and may further include boron (B). In addition, to reduce saturation magnetizations of the first and second magnetic patterns MS1 and MS2, the first and second magnetic patterns MS1 and MS2 may further include at least one of titanium (Ti), aluminum (Al), silicon (Si), magnesium (Mg), or tantalum (Ta). Each of the first and second magnetic patterns MS1 and MS2 may be formed using a sputtering process or a CVD process.

According to some embodiments of the inventive concepts, the bottom electrode and/or the top electrode may be formed of a material of which the surface binding energy with respect to the tunnel barrier pattern is relatively low. As a result, it is possible to inhibit or prevent the electrode material from being re-deposited on the sidewall of the tunnel barrier pattern during the patterning process.

According to some embodiments of the inventive concepts, the bottom electrode may be formed of a material having a low surface binding energy with respect to the tunnel barrier pattern, and the top electrode may be formed of a material having a relatively high etch resistance. As a result, the re-deposition phenomenon may be inhibited, minimized, or prevented without increasing the thickness of the magnetic tunnel junction pattern.

The above-disclosed subject matter is to be considered illustrative, and not restrictive, and the appended claims are intended to cover all such modifications, enhancements, and other embodiments, which fall within the true spirit and scope. Thus, to the maximum extent allowed by law, the scope is to be determined by the broadest permissible interpretation of the following claims and their equivalents, and shall not be restricted or limited by the foregoing detailed description.

What is claimed is:

1. A magnetic memory device comprising:
a bottom electrode on a substrate;
a magnetic tunnel junction pattern comprising a first magnetic layer, a tunnel barrier layer, and a second magnetic layer, which are sequentially stacked on the bottom electrode; and
a top electrode on the magnetic tunnel junction pattern,
wherein the bottom electrode comprises a first material and the top electrode comprises a second material, and
wherein a first surface binding energy of the first material with respect to the magnetic tunnel junction pattern is lower than a second surface binding energy of the second material with respect to the magnetic tunnel junction pattern.

2. The magnetic memory device of claim 1, wherein the first material comprises copper (Cu), germanium (Ge), aluminum (Al), scandium (Sc), carbon (C), titanium (Ti), tantalum (Ta), or vanadium (V).

3. The magnetic memory device of claim 2, wherein the second material comprises tungsten (W).

4. The magnetic memory device of claim 1, wherein a first atomic weight of the first material is lower than a second atomic weight of the second material.

5. The magnetic memory device of claim 1, wherein a first group number of the first material in a periodic table is higher than a second group number of the second material in the periodic table.

6. The magnetic memory device of claim 5,
wherein the first material comprises copper (Cu), aluminum (Al), germanium (Ge), or carbon (C), and
wherein the second material comprises scandium (Sc), titanium (Ti), tantalum (Ta), vanadium (V), or tungsten (W).

7. The magnetic memory device of claim 5,
wherein the bottom electrode comprises copper (Cu), aluminum (Al), germanium (Ge), carbon (C), or any nitride thereof, and
wherein the top electrode comprises scandium (Sc), titanium (Ti), tantalum (Ta), vanadium (V), tungsten (W), or any nitride thereof.

8. The magnetic memory device of claim 1, wherein the top electrode comprises a higher etch resistance to an etching process than the bottom electrode.

9. The magnetic memory device of claim 1,
wherein the top electrode is thicker than the bottom electrode, and
wherein a width of the top electrode is tapered away from the substrate.

10. The magnetic memory device of claim 1, wherein the top electrode comprises:
a metal nitride layer; and
a metal layer on the metal nitride layer.

11. The magnetic memory device of claim 1, wherein the bottom electrode further comprises the second material.

12. The magnetic memory device of claim 11, wherein a weight ratio of the first material to the second material in the bottom electrode ranges from about 1:1 to about 1:20.

13. The magnetic memory device of claim 11,
wherein the top electrode further comprises the first material, and
wherein a first concentration of the first material in the bottom electrode is higher than a second concentration of the first material in the top electrode.

14. A magnetic memory device comprising:
a first electrode on a substrate;
a magnetic tunnel junction pattern comprising a first magnetic layer, a tunnel barrier layer, and a second magnetic layer, which are sequentially stacked on the first electrode; and
a second electrode on the magnetic tunnel junction pattern,
wherein the first electrode is between the second electrode and the substrate, and
wherein at least one of the first electrode or the second electrode comprises a low-energy electrode material comprising a first surface binding energy with respect to the magnetic tunnel junction pattern that is lower than a second surface binding energy of tungsten with respect to the magnetic tunnel junction pattern.

15. The magnetic memory device of claim 14,
wherein the first electrode comprises the low-energy electrode material, and
wherein the second electrode is free of the low-energy electrode material.

16. The magnetic memory device of claim 14, wherein a first concentration of the low-energy electrode material in the first electrode is higher than a second concentration of the low-energy electrode material in the second electrode.

17. The magnetic memory device of claim 16,
wherein the first concentration of the low-energy electrode material in the first electrode ranges from about 15 wt % to about 50 wt %, and
wherein the second concentration of the low-energy electrode material in the second electrode ranges from about 5 wt % to about 15 wt %.

18. The magnetic memory device of claim 14,
wherein the low-energy electrode material comprises copper (Cu), aluminum (Al), germanium (Ge), carbon (C), scandium (Sc), titanium (Ti), tantalum (Ta), or vanadium (V), and
wherein the second electrode comprises a higher etch resistance to an etching process than the first electrode.

19. A magnetic memory device comprising:
a first electrode on a substrate;
a magnetic tunnel junction pattern comprising a first magnetic layer, a tunnel barrier layer, and a second magnetic layer, which are sequentially stacked on the first electrode; and
a second electrode on the magnetic tunnel junction pattern,
wherein the first electrode is between the second electrode and the substrate,
wherein the first electrode comprises a first material and a second material, and the second electrode comprises the second material, and
wherein a first surface binding energy of the first material with respect to the tunnel barrier layer of the magnetic tunnel junction pattern is lower than a second surface binding energy of the second material with respect to the tunnel barrier layer of the magnetic tunnel junction pattern.

20. The magnetic memory device of claim 19,
wherein the second electrode further comprises the first material, and
wherein a first concentration of the first material in the first electrode is higher than a second concentration of the first material in the second electrode.
